(19) United States
(12) Patent Application Publication
(10) Pub. No.: US 2026/0293275 A1
(43) Pub. Date: Sep. 24, 2026

(54) SEMICONDUCTOR DEVICE

(71) Applicant: TAIWAN SEMICONDUCTOR MANUFACTURING COMPANY, LTD., Hsinchu (TW)

(72) Inventors: Yu Ying CHEN, Taoyuan City (TW); Yuyuan HUANG, Changhua County (TW)

(73) Assignee: TAIWAN SEMICONDUCTOR MANUFACTURING COMPANY, LTD., Hsinchu (TW)

(21) Appl. No.: 19/087,916

(22) Filed: Mar. 24, 2025

(51) Int. Cl. H10D 84/01; H01L 21/02; H10D 84/83

(52) U.S. Cl. CPC H10D 84/0153; H10D 84/832; H10P 14/6339; H10P 14/6922

(57) ABSTRACT

A method of forming a semiconductor device comprises the following steps. A first active region and a second active region are formed over a substrate. An isolation feature is formed over the substrate and between the first active region and the second active region along a direction. A first gate structure is formed over the first active region and a second gate structure over the second active region. A gate isolation feature is formed disposed between the first gate structure and the second gate structure along the direction, wherein the gate isolation feature includes a first portion over the isolation feature and a second portion extending into the isolation feature, and the gate isolation feature includes SiOC with a k value less than about 4.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2 through 5, 6A, 13A, 14A, 15A, 16A and 17A illustrate reference cross-section A-A′ illustrated in FIG. 1 that extends through a gate region along a longitudinal axis of the gate region.

FIGS. 6B, 7B, 8B, 9B, 10B, 11B, 11C, 12B, 12D, 13B, 14B, 15B, 16B and 17B illustrate reference cross-section B-B′ illustrated in FIG. 1 that extends through a fin along a longitudinal axis of the fin.

FIGS. 7A, 8A, 9A, 10A, 11A, 12A, 12C, and 13C illustrate reference cross-section C-C′ illustrated in FIG. 1 that extends through source/drain regions along the longitudinal direction of the gate region.

FIG. 17C is a zoomed-in cross-sectional view of the structure shown in FIG. 18A.

FIGS. 17D and 19A illustrate top views of GAA-FETs in gate cut processing in accordance with some embodiments of the present disclosure.

FIGS. 18A-18G illustrate the gate cut step (i.e., cut metal gate step) in accordance with some embodiments.

FIG. 19B illustrates reference cross-section D-D′ illustrated in FIG. 19A.

FIG. 20A illustrates reference cross-section A-A′ illustrated in FIG. 1 that extends through a gate region along a longitudinal axis of the gate region.

FIG. 20B illustrates reference cross-section B-B′ illustrated in FIG. 1 that extends through a fin along a longitudinal axis of the fin.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

In manufacturing semiconductor device, metal gates may include multilayers including work function metal layers and a fill metal which may include a material different from materials of the work function metal layers to provide suitable threshold voltage or conductivity for the semiconductor device. However, the etchant used to etch the fill metal may etch the underlying work function metal layers at a faster etch rate, leading to the opening in the metal gates with a re-entrant profile. Such re-entrant profile often leads to void formation during forming the cut metal gate (CMG) refill because the CMG refill formation may be a conformal deposition process. The void may induce missing of metal gate since a subsequent dry etch process for the source/drain via formation may etch easily through the void and further etch the metal gate, resulting in an undesirable electrical short between source/drain contact and metal gate, or electrical short between source/drain contacts. Other problems like chemical mechanical polishing (CMP) loading issue and negative impact on wafer acceptance test (WAT), yield and reliability may arise unwantedly.

Further, the CMG refill may utilize a bi-layer process. For example, a silicon nitride liner formed by atomic layer deposition (ALD) and a silicon oxide re-fill layer formed by ALD may be formed as CMG refill for metal gate isolation. The oxidation by oxygen plasma in plasma enhanced ALD (ALD) for forming silicon oxide may be detrimental to high-k gate dielectric layer and the metal gate, causing threshold voltage (Vₜ) shift and influencing device performance.

Some embodiments of the present disclosure provide a method of forming Gate isolation structure as the CMG refill using oxidizer-free deposition through siloxane precursor activation and plasma polymerization. Therefore, oxidation of the metal gate can be mitigated and threshold voltage (Vₜ) shift can be reduced. The oxidizer-free deposition may be performed using bottom-up flowable deposition to dissolve void formation issue from PEALD process and prevent electrical short between source/drain contacts. The gate isolation structures may include SiOCₓ with low k, such as lower than about 4 to reduce resistance-capacitance (RC) delay effect by lowering effective capacitance (C_{eff}), thus boosting ring oscillator (RO) performance.

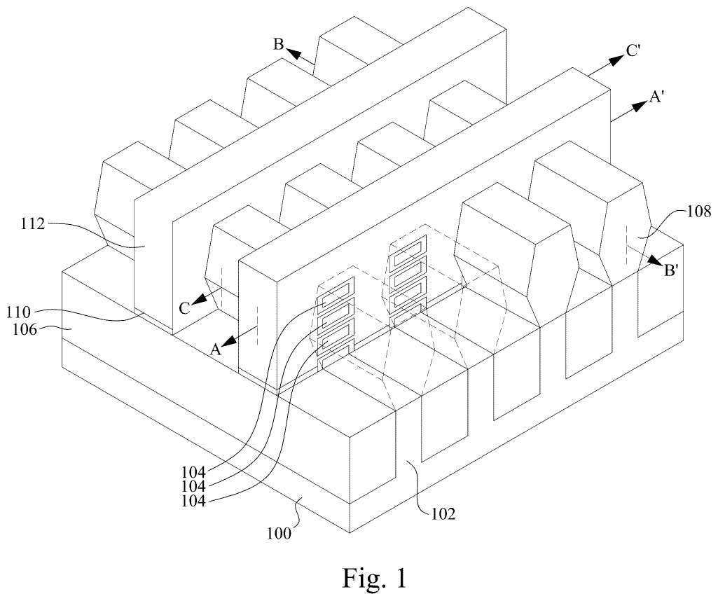

FIG. 1 illustrates an example of GAA-FETs (e.g., nanowire FETs, nanosheet FETs, or the like) in a three-dimensional view, in accordance with some embodiments. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectric layers 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Cross-section C-C′ is parallel to cross-section A-A′ and extends through epitaxial source/drain regions of the GAA-FETs. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

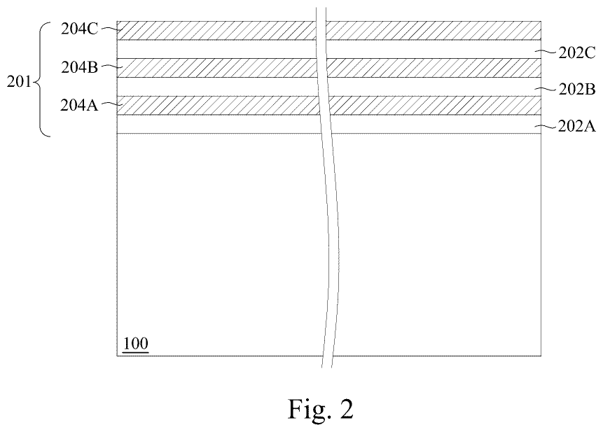

FIGS. 2 through 20B are cross-sectional views and top views of intermediate stages in the manufacturing of GAA-FETs, in accordance with some embodiments.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). The second semiconductor layers 204 can be referred to as second semiconductor structures or second active regions. For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

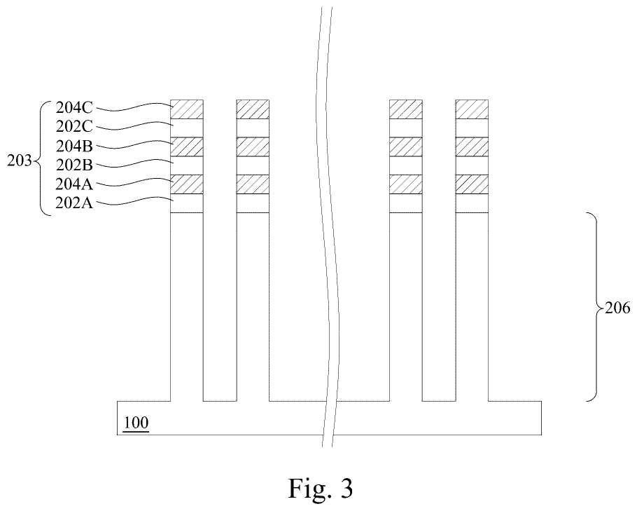

Referring now to FIG. 3, fin structures 206 are formed in the substrate 100 and nanostructures 203 are formed in the multi-layer stack 201, in accordance with some embodiments. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 203 can be collectively referred to as a semiconductor fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

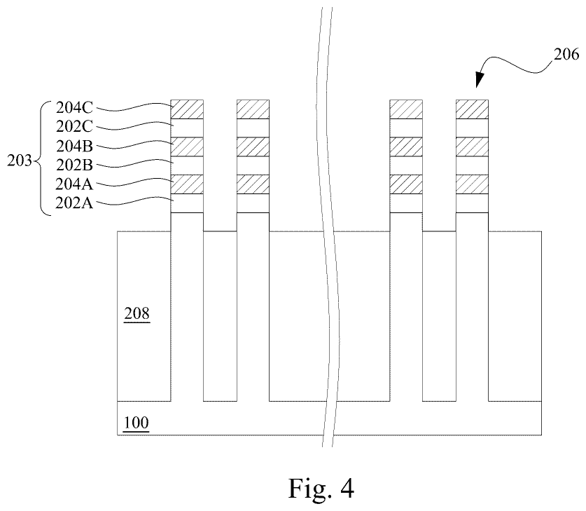

In FIG. 4, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The STI regions 208 can be referred to as isolation structures or isolation features. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 4, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

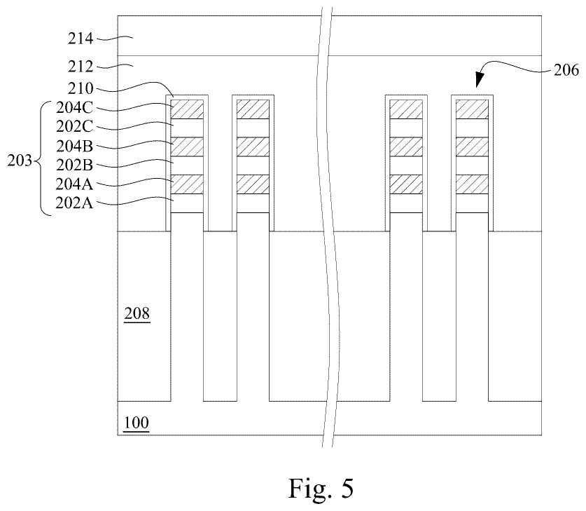

In FIG. 5, a dummy dielectric layer 210 is formed on the fin structures 206 and/or the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a mask layer 214 is formed over the dummy gate layer 212. The dummy gate layer 212 may be deposited over the dummy dielectric layer 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

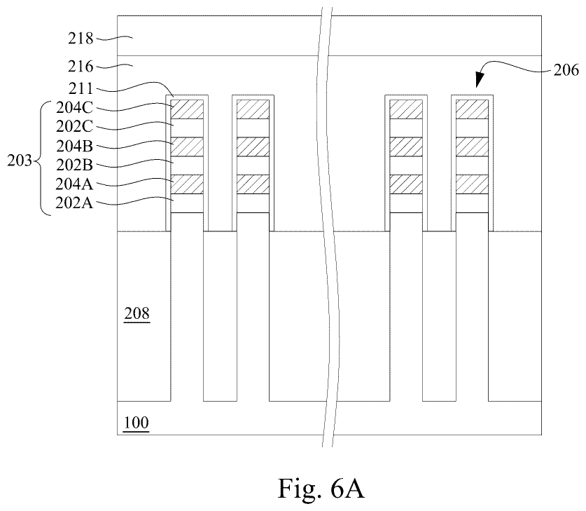

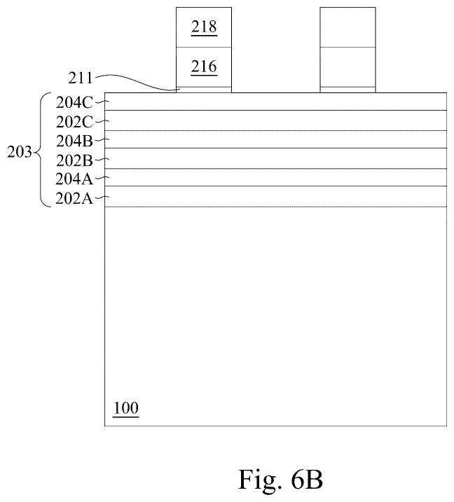

In FIGS. 6A and 6B, the mask layer 214 (see FIG. 5) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

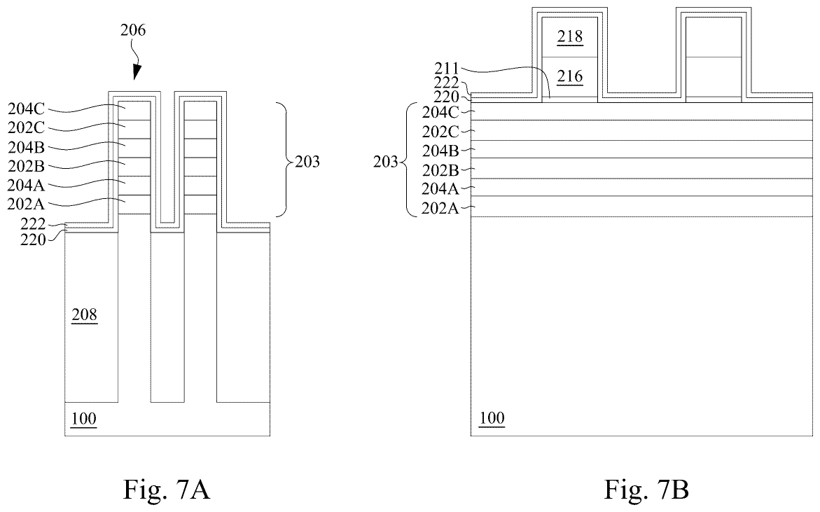

In FIGS. 7A and 7B, a first spacer layer 220 and a second spacer layer 222 are formed over the structures illustrated in FIGS. 6A and 6B, respectively. The first spacer layer 220 and the second spacer layer 222 will be subsequently patterned to act as spacers for forming self-aligned source/drain regions. In FIGS. 7A and 7B, the first spacer layer 220 is formed on top surfaces of the STI regions 208; top surfaces and sidewalls of the fin structures 206, the nanostructures 203, and the masks 218; and sidewalls of the dummy gates 216 and the dummy gate dielectric 211. The second spacer layer 222 is deposited over the first spacer layer 220. The first spacer layer 220 may be formed of silicon oxide, silicon nitride, silicon oxynitride, or the like, using techniques such as thermal oxidation or deposited by CVD, ALD, or the like. The second spacer layer 222 may be formed of a material having a different etch rate than the material of the first spacer layer 220, such as silicon oxide, silicon nitride, silicon oxynitride, or the like, and may be deposited by CVD, ALD, or the like.

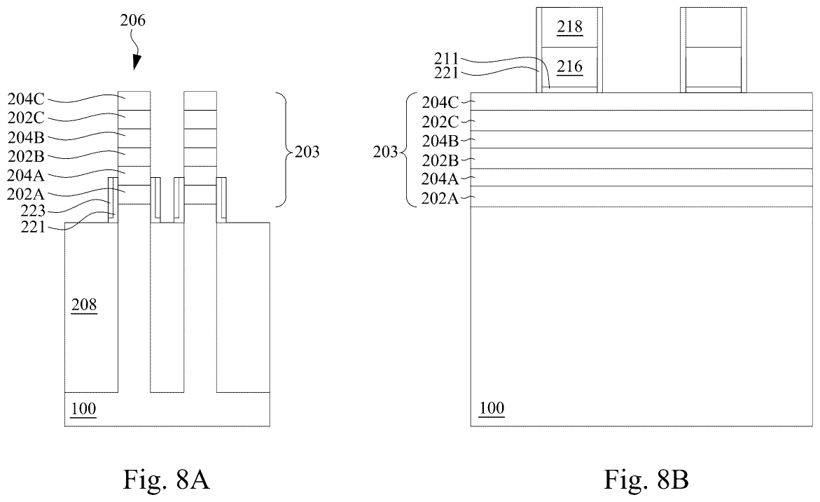

In FIGS. 8A and 8B, the first spacer layer 220 and the second spacer layer 222 are etched to form first spacers 221 and second spacers 223. As will be discussed in greater detail below, the first spacers 221 and the second spacers 223 act to self-align subsequently formed source and drain regions (collectively referred to as source/drain regions), as well as to protect sidewalls of the fin structures 206 and/or nanostructure 203 during subsequent processing. The first spacer layer 220 and the second spacer layer 222 may be etched using a suitable etching process, such as an isotropic etching process (e.g., a wet etching process), an anisotropic etching process (e.g., a dry etching process), or the like. In some embodiments, the material of the second spacer layer 222 has a different etch rate than the material of the first spacer layer 220, such that the first spacer layer 220 may act as an etch stop layer when patterning the second spacer layer 222 and such that the second spacer layer 222 may act as a mask when patterning the first spacer layer 220. For example, the second spacer layer 222 may be etched using an anisotropic etch process wherein the first spacer layer 220 acts as an etch stop layer, wherein remaining portions of the second spacer layer 222 form second spacers 223 as illustrated in FIG. 8A. Thereafter, the second spacers 223 acts as a mask while etching exposed portions of the first spacer layer 220, thereby forming first spacers 221 as illustrated in FIG. 8A.

As illustrated in FIG. 8A, the first spacers 221 and the second spacers 223 are disposed on sidewalls of the fin structures 206 and/or nanostructures 203. In some embodiments, the spacers 221 and 223 only partially remain on sidewalls of the fin structures 206. In some embodiments, no spacer remains on sidewalls of the fin structures 206. As illustrated in FIG. 8B, in some embodiments, the second spacer layer 222 may be removed from over the first spacer layer 220 adjacent the masks 218, the dummy gates 216, and the dummy gate dielectrics 211, and the first spacers 221 are disposed on sidewalls of the masks 218, the dummy gates 216, and the dummy gate dielectrics 211. In other embodiments, a portion of the second spacer layer 222 may remain over the first spacer layer 220 adjacent the masks 218, the dummy gates 216, and the dummy gate dielectrics 211.

In some embodiments, the first spacers 221 on gate sidewalls (also called gate spacers) have a small thickness (e.g., in a range from about 1 nm to about 10 nm) so as to reduce gate-to-gate pitch without significant reduction in source/drain region size. In some embodiments, the first spacers 221 on gate sidewalls is formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts.

The above disclosure generally describes a process of forming spacers. Other processes and sequences may be used. For example, fewer or additional spacers may be utilized, different sequence of steps may be utilized (e.g., the first spacers 221 may be patterned prior to depositing the second spacer layer 222), additional spacers may be formed and removed, and/or the like.

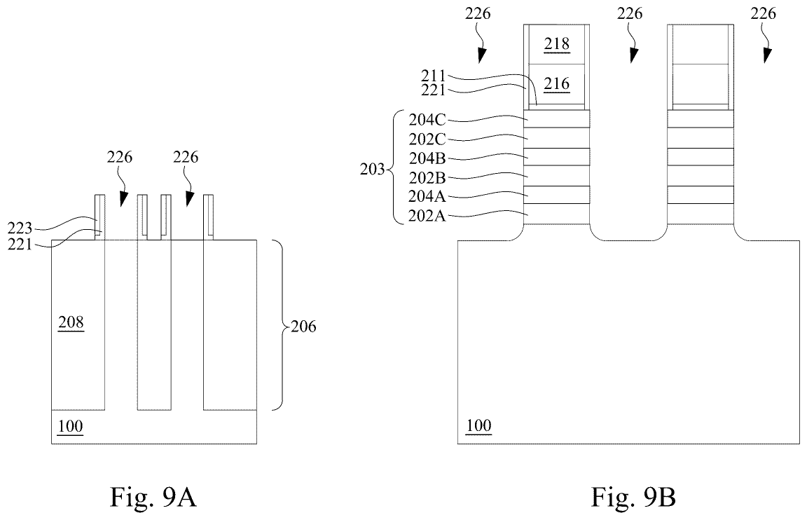

In FIGS. 9A and 9B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 9A, bottom surfaces of the source/drain recesses 226 may be level with top surfaces of the STI regions 208, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

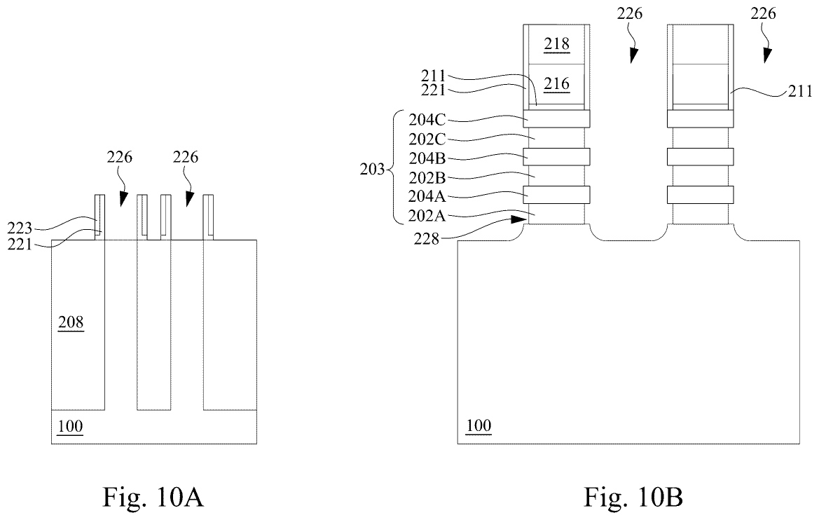

In FIGS. 10A and 10B, portions of sidewalls of the layers of the nanostructures 203 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in the sidewall recesses 228 are illustrated as being straight in FIG. 10B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

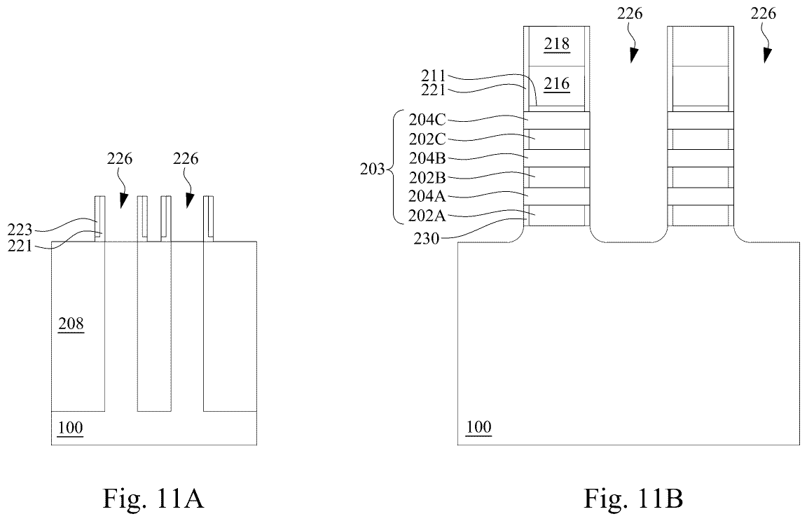

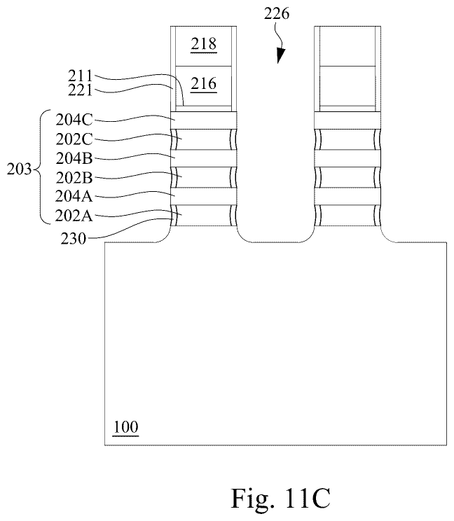

In FIGS. 11A-11C, inner spacers 230 are formed in the sidewall recesses 228. The inner spacers 230 may be formed by depositing an inner spacer layer (not separately illustrated) over the structures illustrated in FIGS. 10A and 10B. The inner spacers 230 act as isolation features between subsequently formed source/drain regions and gate structure. As will be discussed in greater detail below, source/drain regions will be formed in the source/drain recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

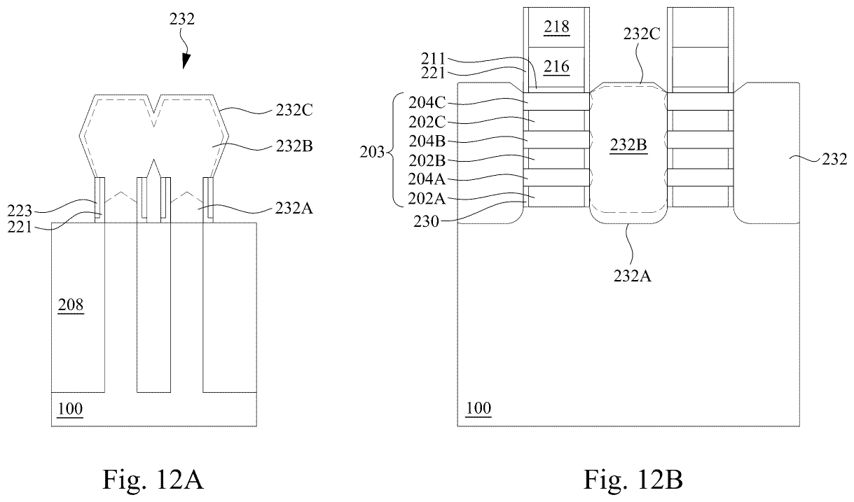

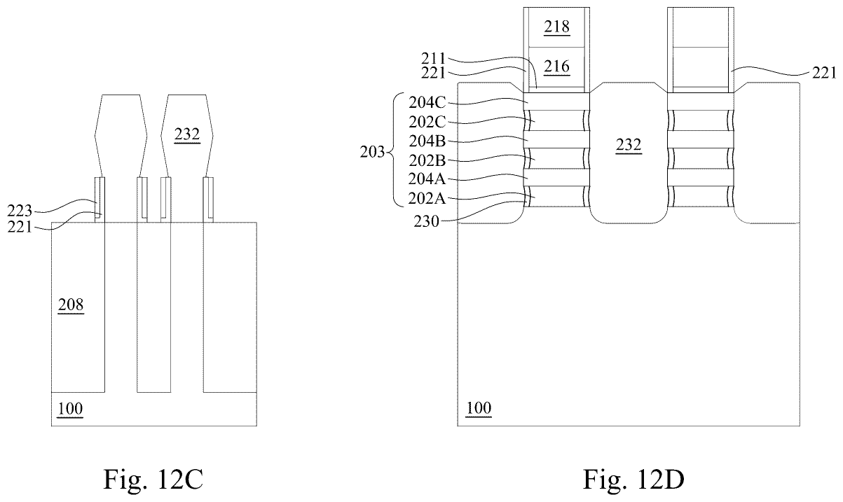

Moreover, although the outer sidewalls of the inner spacers 230 are illustrated as being straight in FIG. 11B, the outer sidewalls of the inner spacers 230 may be concave or convex. As an example, FIG. 11C illustrates an embodiment in which sidewalls of the first nanostructures 202 are concave, outer sidewalls of the inner spacers 230 are concave, and the inner spacers are recessed from sidewalls of the second nanostructures 204. The inner spacer layer may be etched by an anisotropic etching process, such as RIE, NBE, or the like. The inner spacers 230 may be used to prevent damage to subsequently formed source/drain regions (such as the epitaxial source/drain regions 232, discussed below with respect to FIGS. 12A-12D) by subsequent etching processes, such as etching processes used to form gate structures.

In FIGS. 12A-12D, epitaxial source/drain regions 232 are formed in the source/drain recesses 226. In some embodiments, the epitaxial source/drain regions 232 may exert stress on the second nanostructures 204, thereby improving device performance. As illustrated in FIG. 12B, the epitaxial source/drain regions 232 are formed in the source/drain recesses 226 such that each dummy gate 216 is disposed between respective neighboring pairs of the epitaxial source/drain regions 232. In some embodiments, the first spacers 221 are used to separate the epitaxial source/drain regions 232 from the dummy gate layer 212, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the epitaxial source/drain regions 232 may be in situ doped during growth.

As a result of the epitaxy processes used to form the epitaxial source/drain regions 232, upper surfaces of the epitaxial source/drain regions 232 have facets which expand laterally outward beyond sidewalls of the nanostructures 203. In some embodiments, these facets cause adjacent epitaxial source/drain regions 232 to merge as illustrated by FIG. 12A. In some other embodiments, adjacent epitaxial source/drain regions 232 remain separated after the epitaxy process is completed as illustrated by FIG. 12C. In the embodiments illustrated in FIGS. 12A and 12C, the first spacers 221, 223 may be formed to a top surface of the STI regions 208 thereby blocking the lateral epitaxial growth. In some other embodiments, the spacer etch used to form the first spacers 221, 223 may be adjusted to remove the spacer material to allow the epitaxially grown region to extend to the surface of the STI region 208.

The epitaxial source/drain regions 232 may comprise one or more semiconductor material layers. For example, the epitaxial source/drain regions 232 may comprise a first semiconductor material layer 232A, a second semiconductor material layer 232B, and a third semiconductor material layer 232C, which are distinguished in FIGS. 12A and 12B by using dash lines. Any number of semiconductor material layers may be used for the epitaxial source/drain regions 232. Each of the first semiconductor material layer 232A, the second semiconductor material layer 232B, and the third semiconductor material layer 232C may be formed of different semiconductor materials and may be doped to different dopant concentrations. In some embodiments, the first semiconductor material layer 232A may have a dopant concentration less than the second semiconductor material layer 232B and greater than the third semiconductor material layer 232C. In embodiments in which the epitaxial source/drain regions 232 comprise three semiconductor material layers, the first semiconductor material layer 232A may be deposited, the second semiconductor material layer 232B may be deposited over the first semiconductor material layer 232A, and the third semiconductor material layer 232C may be deposited over the second semiconductor material layer 232B.

FIG. 12D illustrates an embodiment in which sidewalls of the first nanostructures 202 are concave, outer sidewalls of the inner spacers 230 are concave, and the inner spacers 230 are recessed from sidewalls of the second nanostructures 204. As illustrated in FIG. 12D, the epitaxial source/drain regions 232 may be formed in contact with the inner spacers 230 and may extend past sidewalls of the second nanostructures 204.

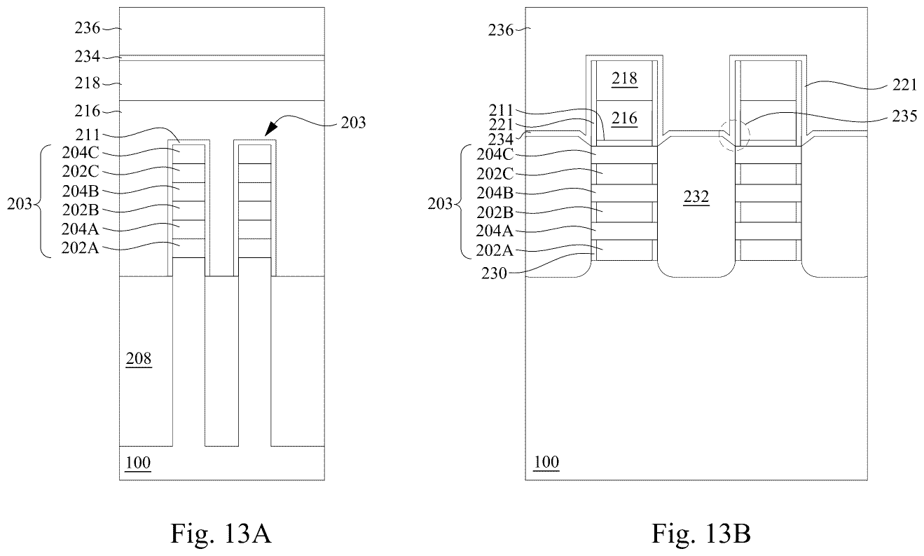

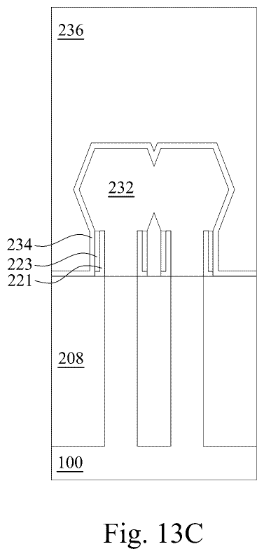

In FIGS. 13A-13C, an interlayer dielectric (ILD) layer 236 is deposited over the structure illustrated in FIGS. 12A-12D. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the epitaxial source/drain regions 232, the mask layer 214, and the first spacers 221. The CESL 234 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236. The CESL 234 may extend along a sidewall of the dummy gates 216. In some embodiments, the CESL 234 has a portion 235 between the ILD layer 236 and the epitaxial source/drain regions 232 having a non-linear profile.

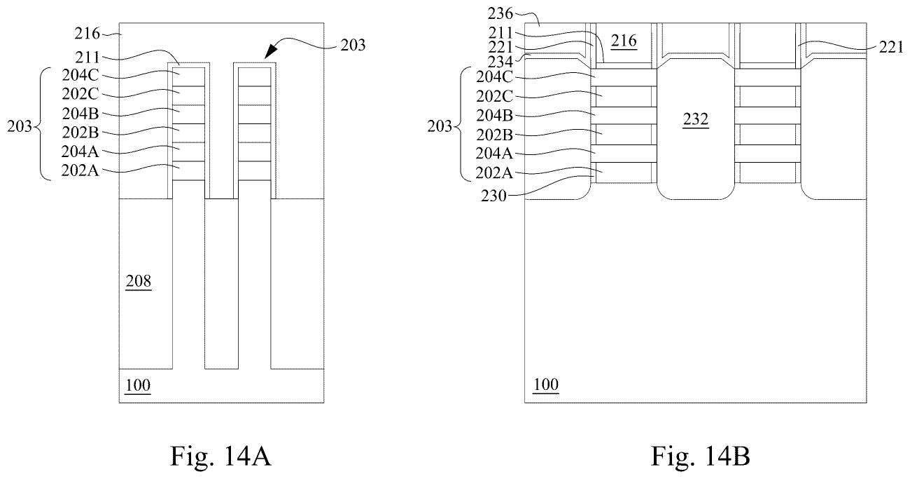

In FIGS. 14A-14B, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gate layer 212 are exposed through the ILD layer 236. In some embodiments, the masks 218 may remain, in which case the planarization process levels the top surface of the ILD layer 236 with top surface of the masks 218 and the first spacers 221.

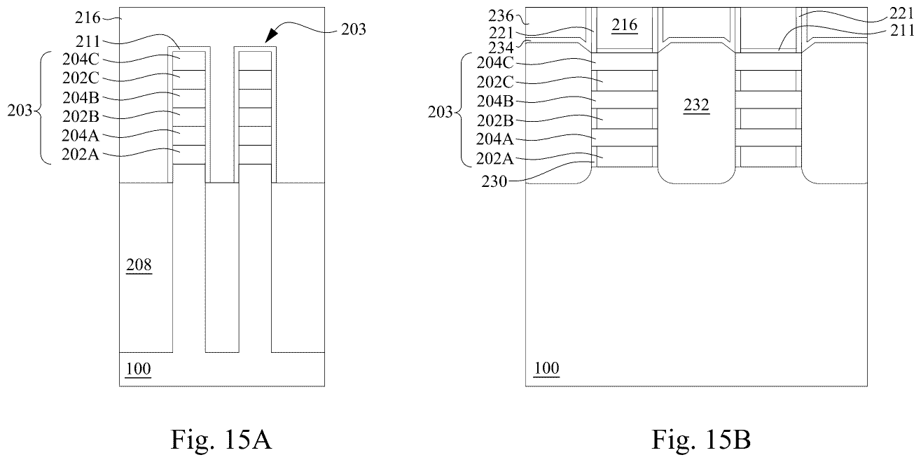

In FIGS. 15A and 15B, the dummy gates 216, and the masks 218 if present, are removed in one or more etching steps, so that gate trenches 238 are formed between corresponding gate spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the first spacers 221. Each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy gate dielectrics 211 may be used as etch stop layers when the dummy gates 216 are etched. The dummy gate dielectrics 211 may then be removed after the removal of the dummy gates 216.

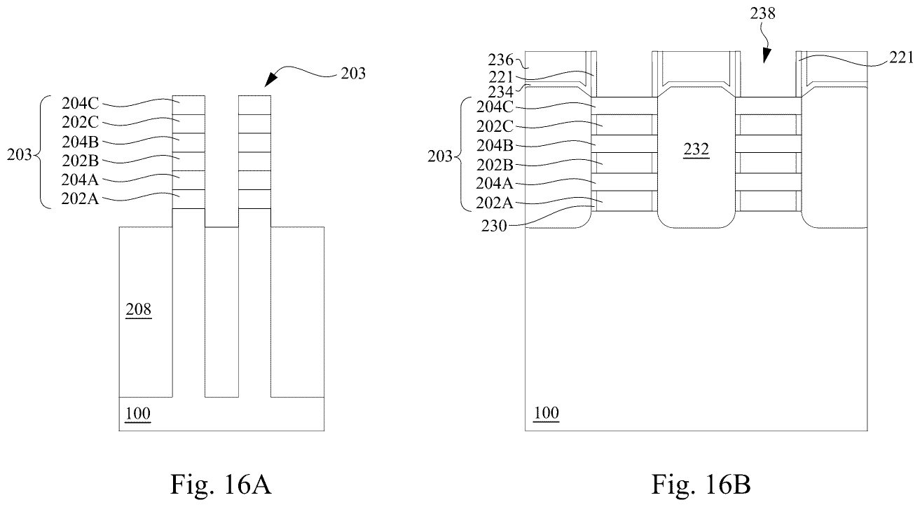

In FIGS. 16A and 16B, the first nanostructures 202 in the gate trenches are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 10A-10B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

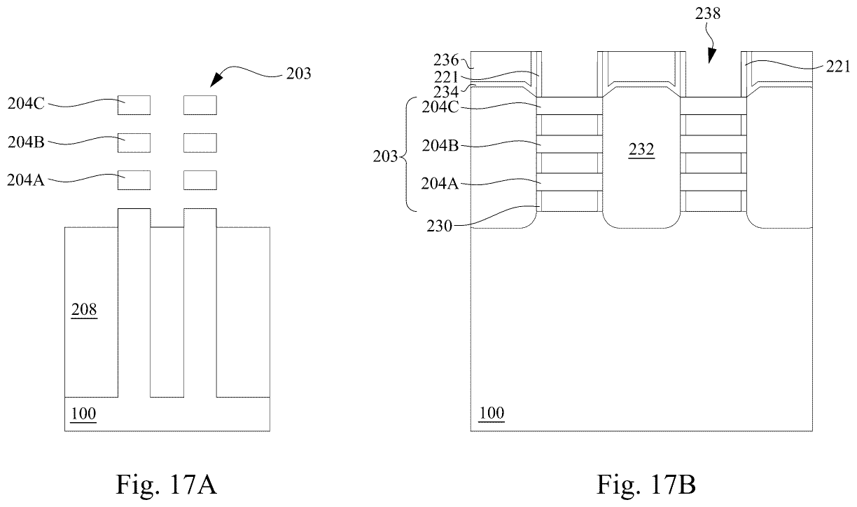

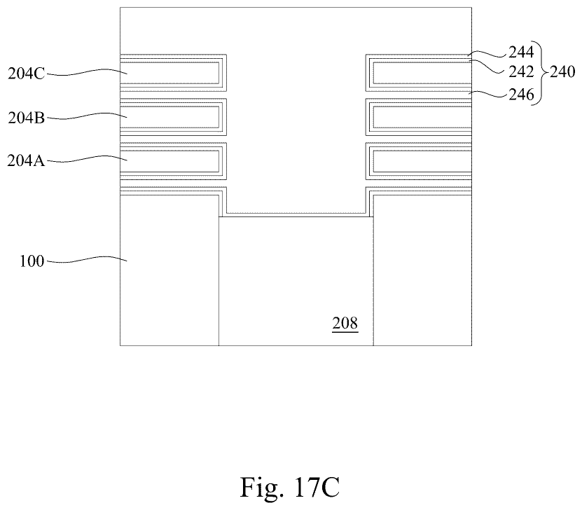

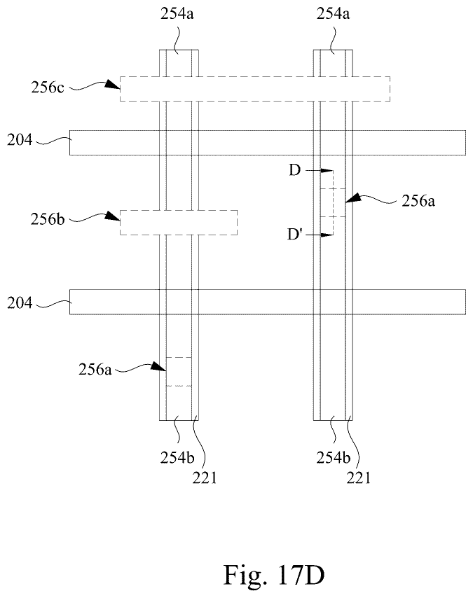

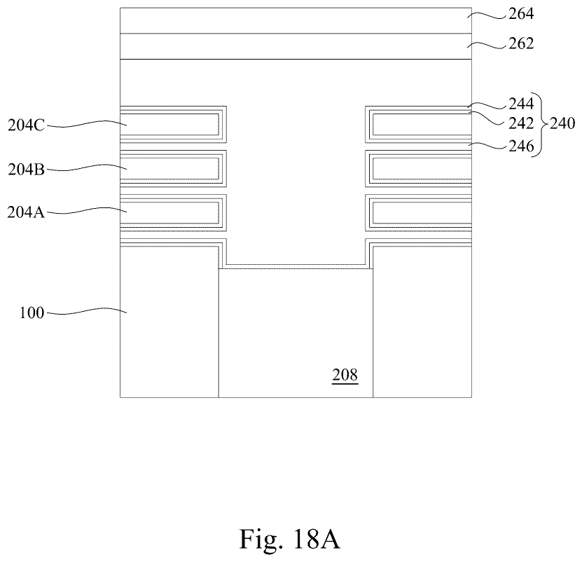

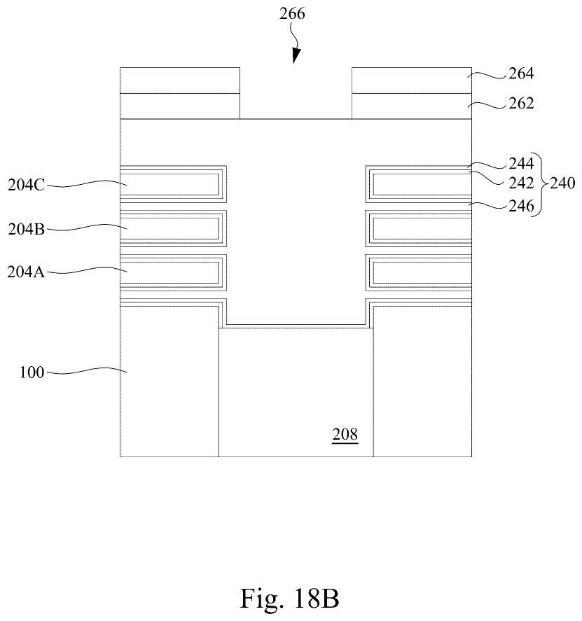

FIG. 17C is a zoomed-in cross-sectional view of the structure shown in FIG. 17A. In FIGS. 17A-17C, high-k/metal gate structures 240 are respectively formed in the gate trenches 238 to surround each of the nanosheets 204 suspended in the gate trenches 238. The high-k/metal gate structures 240 may be final gates of GAA FETs. The replacement gate structures 240, the epitaxial source/drain regions 232 and the channel regions (the nanosheets 204) serve as a transistor. The final gate structure may be a high-k/metal gate stack, however other compositions are possible. In some embodiments, each of the high-k/metal gate structures 240 forms the gate associated with the multi-channels provided by the plurality of nanosheets 204. For example, high-k/metal gate structures 240 are formed within the sheet-to-sheet spaces provided by the release of nanosheets 204. In various embodiments, the high-k/metal gate structure 240 includes an interfacial layer 242 formed around the nanosheets 204, a high-k gate dielectric layer 244 formed around the interfacial layer 242, and a gate metal layer 246 formed around the high-k gate dielectric layer 244 and filling a remainder of gate trenches 238. Formation of the high-k/metal gate structures 240 may include one or more deposition processes to form various gate materials, followed by a CMP process to remove excessive gate materials, resulting in the high-k/metal gate structures 240 having top surfaces level with a top surface of the ILD layer 236. As illustrated in the cross-sectional view of FIGS. 17A and 17C, the high-k/metal gate structure 240 surrounds each of the nanosheets 204, and thus is referred to as a gate of a GAA FET. In some embodiments, a dielectric constant of the first spacers 221 is less than a dielectric constant of the high-k gate dielectric layer 244.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form the interfacial layer 242.

In some embodiments, the high-k gate dielectric layer 244 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240. For an n-type GAA FET, the gate metal layer 246 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate metal layer 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

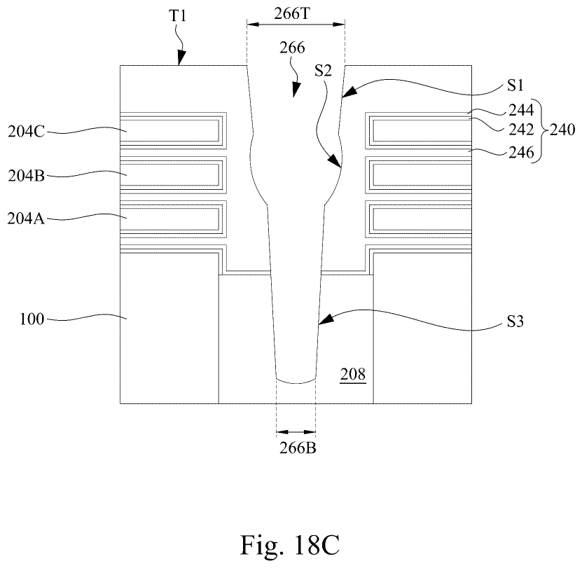

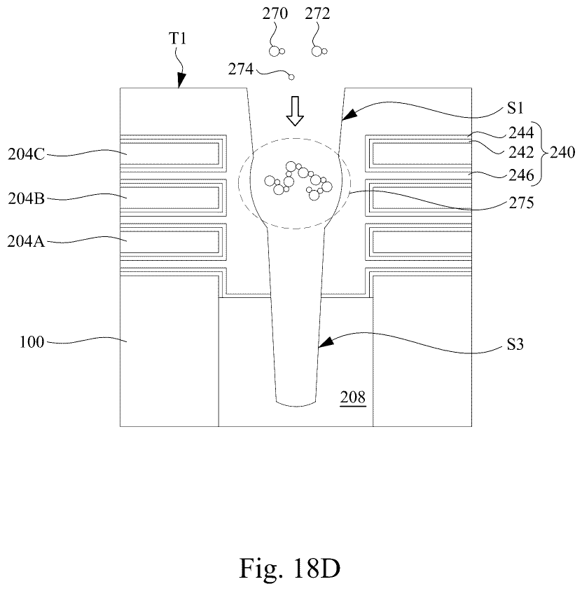

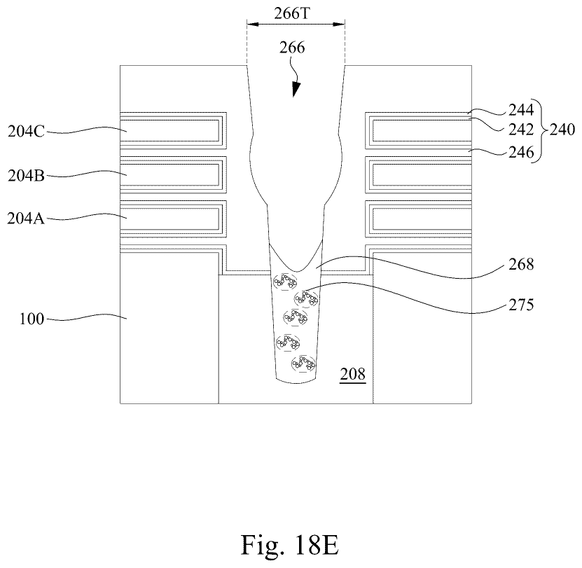

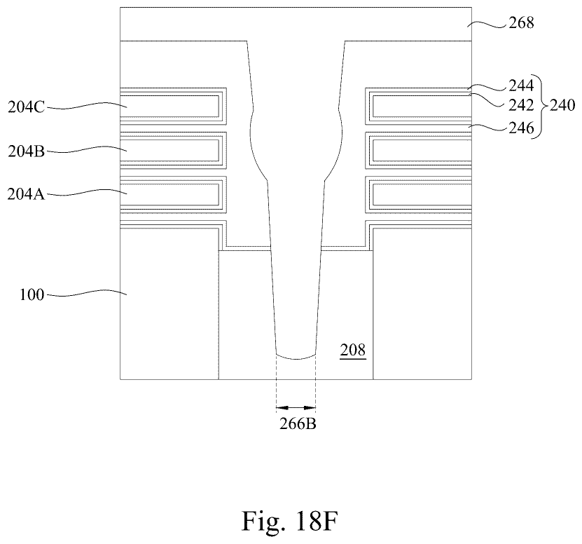

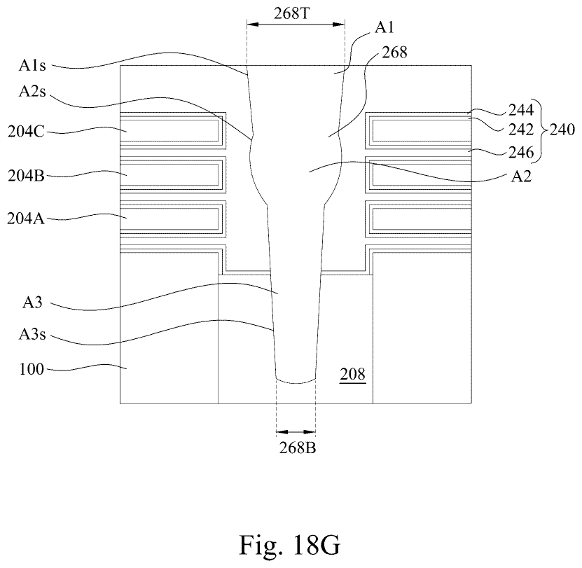

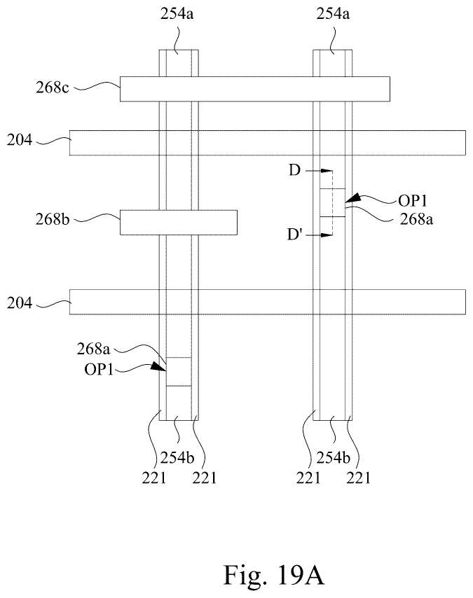

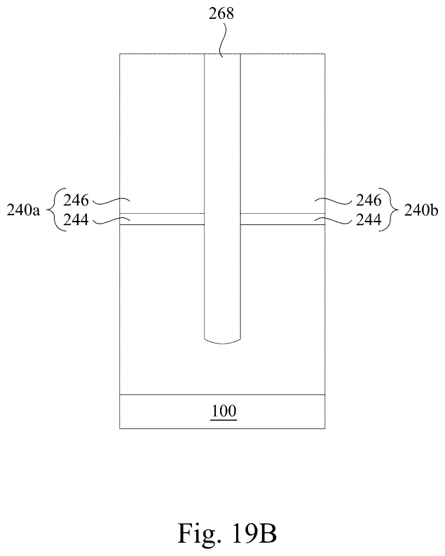

FIGS. 18A-18G illustrate the gate cut step (i.e., cut metal gate step) in accordance with some embodiments. In this step, a patterned mask (e.g., patterned photoresist) is first formed over the substrate 100, except for CMG target regions 256a, 256b, 256c as illustrated in FIG. 17D, and then one or more etching processes are performed on the exposed CMG target regions 256a, 256b, 256c to form gate cut openings 266 (see FIG. 18C) each breaking the continuous high-k/metal gate structure 240 into separate gate structures 240a, 240b (see FIG. 19B) and breaking a continuous gate refill metal structure 254 into separate gate refill metal structures 254a, 254b. In some embodiments, the CMG target region 256a can be between the first spacers 221, the CMG target region 256b can extend across the first spacers 221, and the CMG target region 256c can be extend across the gate refill metal structures 254a, 254b. Afterwards, gate isolation structures 268 are formed in the gate cut openings 266, so as to electrically isolate the separate gate structures 240a, 240b, and the gate refill metal structures 254a, 254b. The gate isolation structures 268 may then be disposed between and interfaces the first spacers 221.

As shown in FIG. 18A, one or more hard mask layers can be formed over the gate metal layer 246 of the high-k/metal gate structures 240. Two hard mask layers 262 and 264 are illustrated in this example. In an embodiment, the hard mask layer 262 includes titanium nitride, while the hard mask layer 264 includes silicon nitride. In the present embodiment, the material for the hard mask layer 262 is chosen to have good adhesion with the gate metal layer 246 yet not reactive with the gate metal layer 246. The hard mask layers 262 and 264 may be deposited using CVD, PVD, ALD, or other suitable methods.

Referring to FIG. 18B, the hard mask layers 262 and 264 are patterned (e.g., etched) to provide an opening 266 that exposes the gate metal layer 246. In an example, a patterned photoresist is formed over the hard mask layers 262 and 264 by photoresist coating, exposing, post-exposure baking, and developing. Then, the hard mask layers 262 and 264 can be etched using the patterned photoresist as an etch mask to form the opening 266. The etching process may include wet etching, dry etching, reactive ion etching, or other suitable etching methods. The patterned photoresist is removed thereafter, for example, by resist stripping. It is noted that the sidewalls of the opening 266 at the hard mask layers 262 and 264 are vertical or nearly vertical.

The gate metal layer 246 can then be etched through the opening 266. The patterned hard mask layers 262 and 264 protect the rest of the gate metal layer 246 from the etching process. Referring to FIG. 18C, the opening 266 can extend down and through the gate metal layer 246 and into the STI regions 208. In some embodiments, the opening 266 can have a curved bottom surface. Particularly, the etching process is performed such that the opening 266 has a re-entrant profile. The etching process may use one or more etchants or a mixture of etchants that etch the various layers in the gate metal layer 246. The etchant used at first for etching the fill metal may etch the underlying work function metal layers at a faster rate, causing laterally widened opening 266. For example, the gate metal layer 246 can have an upper sidewall S1, a middle sidewall S2 and a lower sidewall S3. The upper sidewall S1 and the lower sidewall S3 may be slanted relative to a top surface T1 of the gate metal layer 246. In some embodiments, the middle sidewall S2 may be curved and concave. For example, the middle sidewall S2 can be referred to as curved middle sidewall or curved sidewall. In some embodiments, the opening 266 can have a top width 266T and a bottom width 266B smaller than the top width 266T. In other words, the opening 266 becomes narrower in a direction toward the substrate 100.

A gate isolation structure or gate isolation feature (see 268 in FIG. 18G) may then be formed in the opening 266. In some embodiments, the Gate isolation structure 268 can be formed by flowable CVD (FCVD) process. Reference is made to FIG. 18D. In some embodiments, the FCVD process for forming the Gate isolation structure 268 can performed by pulsing a first precursor 270, pulsing a second precursor 272 and pulsing a reactant 274 to the opening 266 in the high-k/metal gate structure 240 over the substrate 100. For example, the first precursor 270 can include a siloxane precursor or a silicon-containing monomer including an Si—O—R group in which R can be a hydrocarbon group such as CH₃ or C₂H₅, and the second precursor 272 can include a siloxane precursor or a silicon-containing monomer including an Si—H group. In some embodiments, the reactant 274 can include NHₓ gas, Ar gas, H₂ gas, a combination thereof, or the like. The first precursor 270, the second precursor 272 and the reactant 274 can be oxidizer-free. Therefore, oxidation of the high-k/metal gate structures 240 can be mitigated and threshold voltage (Vₜ) shift can be reduced.

In some embodiments, the first precursor 270 and the second precursor 272 can be activated through radicals and electrons provided by, for example, the reactant 274. In some embodiments, the first precursor 270, the second precursor 272 and the reactant 274 can be in gas phases. The Si—O—R group of the first precursor 270 can react with the radicals of the reactant 274, such as, NHx*, Ar*, H*, e⁻, and be cleaved thereby to form Si—O* group. The Si-H group of the second precursor 272 can react with the radicals of the reactant 274, such as, NHx*, Ar*, H*, e⁻, and be cleaved thereby to form Si* group. The Si—O* group and the Si—H group can then crosslink to form a product 275 including Si—O—Si group, which the crosslink reaction between the Si—O* group and the Si—H group can be referred to as plasma polymerization.

Reference is made to FIG. 18E. In beginning of depositing the gate isolation structure 268, the gate isolation structure 268 can be only deposited on a bottom of the opening 266 and not be deposited on a top surface of the high-k/metal gate structure 240 due to a bottom-up flowable deposition, which will be discussed in greater detail below. In other words, the top surface of the high-k/metal gate structure 240 is free from the gate isolation structure 268. In some embodiments, the Gate isolation structure 268 can include carbon. For example, the Gate isolation structure 268 can include SiO, SiOC, or a combination thereof. The carbon concentration in the Gate isolation structure 268 can be tuned by the materials of the first precursor 270, the second precursor 272, Si—O—R group cleavage of the first precursor 270, Si—H group cleavage of the second precursor 272 through flux and/or density of radicals (NHx*, Ar* and H*) or electrons (e⁻) provided by the reactant 274.

In some embodiments, the flux and/or density of the NHx*, Ar* and H*, e⁻ can be controlled by plasma power and flow rate of the NHₓ gas, Ar gas, H₂ gas during the FCVD process to form the Gate isolation structure 268. For example, during the FCVD process to form the Gate isolation structure 268, the plasma power can be in a range from about 50 W to about 2000 W, the flow rate of the NHₓ gas can be in a range from about 10 sccm to about 2000 sccm, and the temperature can be in a range from about 25° C. to about 400° C. Since the Gate isolation structure 268 is formed using oxidizer-free deposition through the siloxane precursor activation and plasma polymerization, oxidation of the metal gate can be mitigated and threshold voltage (Vₜ) shift can be reduced.

In some embodiments, a post plasma treatment can be performed to tune the carbon concentration in the Gate isolation structure 268, which will be discussed in greater detail below. In some embodiments, the Gate isolation structure 268 can have a carbon atomic concentration in a range from about 0% to about 60%. In some embodiments, the Gate isolation structure 268 can have a k-value of about 2.5 to about 5, such as 4 or lower than 4. In some embodiments, the Gate isolation structure 268 can include Si—C bond, C—O bond, or a combination thereof, which can be observed by X-ray photoelectron spectroscopy (XPS), or Fourier transform infrared spectroscopy (FTIR). In some embodiments, the Gate isolation structure 268 can have a k value less than k value (e.g., 7) of the silicon nitride or less than the k value (e.g., 4) of the silicon oxide. The Gate isolation structure 268 may include SiOCx with low k, such as lower than about 4 and thus can reduce resistance-capacitance (RC) delay effect, by lowering effective capacitance (Ceff), thus boosting ring oscillator (RO) performance.

In some embodiments, the top width 266T of the opening 266 can be less than about 100 nm, such as in a range from about 1 nm to about 100 nm, so that the top width 266T is narrow enough such that condensation rate of the product 275 for forming the Gate isolation structure 268 can be increased, which is beneficial for growing increased molecular weight (MW) material. Such increased molecular weight may result in high boiling point for the Gate isolation structure 268. Therefore, it becomes easier for condensation of the Gate isolation structure 268 from bottom, which can facilitate bottom-up growth of the Gate isolation structure 268. In other words, the bottom-up growth deposition of the Gate isolation structure 268 in the deep opening 266 can be achieved by capillary condensation. Unwanted void formation issue for the Gate isolation structure 268 which may be caused by PEALD process can be prevented. Electrical short between source/drain contacts can be prevented as well.

Reference is made to FIG. 18F. As discussed previously with regard to FIG. 18E, due to the bottom-up growth of the Gate isolation structure 268, the opening 266 can be filled by the Gate isolation structure 268 with seam free or void free.

After the opening 266 is filled by the Gate isolation structure 268, a planarization operation, such as CMP, can be performed on the structure in FIG. 18E until the gate metal layer 246 is exposed, as shown in FIG. 18G. Since the Gate isolation structure 268 can inherent the profile of the opening 266, the Gate isolation structure 268 can have a top width 268Tand a bottom width 268B less than the top width 268T. For example, the Gate isolation structure 268 can have a top portion A1, a middle portion A2 and a bottom portion A3 in which the middle portion A2 is vertically between the top portion A1 and the bottom portion A3. In some embodiments, the top portion A1 can have opposite slanted sidewalls A1s, and the bottom portion can have opposite slanted sidewalls S2s. The middle portion A2 can have opposite curved sidewalls A2s, such as convex sidewalls. In other words, curved sidewalls A2s can have a curvature greater than a curvature of slanted sidewalls A1s and a curvature of the slanted sidewalls A3s. In some embodiments, the middle portion A2 can have a maximum width greater than the bottom width 268B.

FIG. 19A illustrates a top view of the semiconductor device in FIG. 18G which is after the gate cut step in accordance with some embodiments of the present disclosure. FIG. 19B illustrates reference cross-section D-D′ illustrated in FIG. 19A. The Gate isolation structure 268 can break the continuous high-k/metal gate structure 240 into separate gate structures 240a, 240b. In some embodiments, the gate isolation structures 268a can be between the first spacers 221, the gate isolation structures 268b can extend across the first spacers 221, and the gate isolation structures 268c can extend across the gate refill metal structures 254a, 254b. Afterwards, gate isolation structures 260 are formed in the gate cut openings OP1, so as to electrically isolate the separate gate structures 240a, 240b, and the gate refill metal structures 254a, 254b.

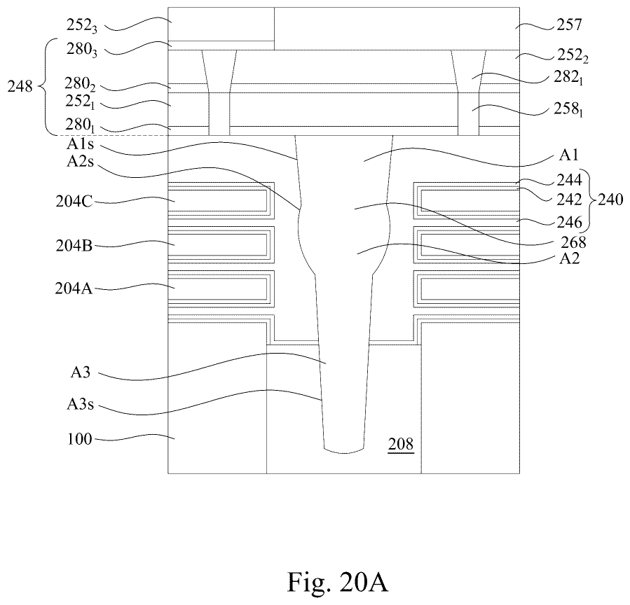

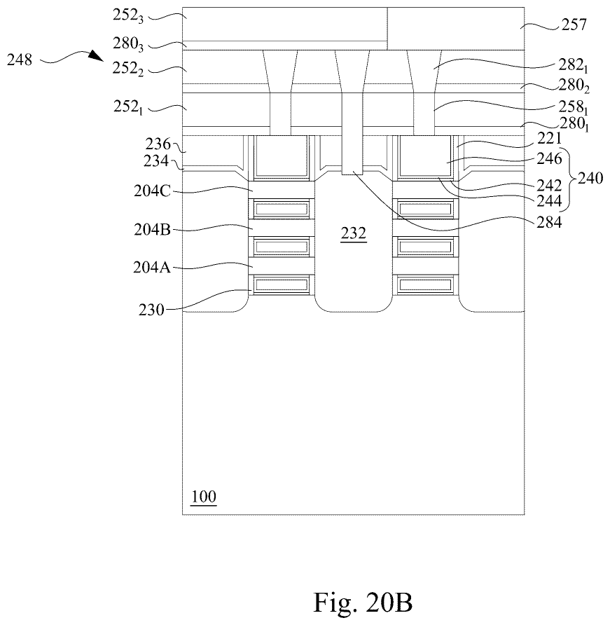

FIG. 20A illustrates reference cross-section A-A′ illustrated in FIG. 1 that extends through a gate region along a longitudinal axis of the gate region. FIG. 20B illustrates reference cross-section B-B′ illustrated in FIG. 1 that extends through a fin along a longitudinal axis of the fin. In some embodiments, an interconnect structure 248 can be disposed on the substrate 100. In some embodiments, the interconnect structure 248 of the semiconductor device may include a plurality of dielectric layers 252₁, 252₂, 252₃, etch stop layers 280₁, 280₂ 280₃, metal vias 282₁, 282₂, a conductive line 257, and gate contacts 258₁, source/drain contacts 258₂). The metal vias 282₁, 282₂, the conductive line 257, and/or the gate contacts 258₁, source/drain contacts 258₂ may be routed through the dielectric layers 252₁, 252₂ and/or etch stop layers 280₁, 280₂ to make connection between the transistor and the external electronic members. For example, as shown in FIGS. 20A-20B, the etch stop layer 280₁ the dielectric layer 252₁, the etch stop layer 280₂, the dielectric layer 2522, the etch stop layer 280₃ and the dielectric layer 252₃ are arranged and stacked in a sequence from bottom to top. The gate contacts 258₁ are routed through the dielectric layer 252₁ and/or the etch stop layer 280₁ to make connections between the metal vias 282₁ and the high-k/metal gate structure 240 and/or between the conductive line 257. The source/drain contacts 258₂ is routed through the dielectric layer 252₁, the etch stop layer 280₁, the CESL 234 and the ILD layer 236 to make connections between the metal vias 282₂ and the epitaxial source/drain regions 232. In some embodiments, the conductive line 257, the gate contacts 258₁, source/drain contacts 258₂ and the metal vias 282₁, 282₂ may include metal based materials, e.g., copper (Cu), that have a good conductive property. In some embodiments, a silicide layer 284 is formed at portions of the epitaxial source/drain regions 232 exposed at bottoms of the contact openings. The silicide layer 284 can be formed by depositing a metal, such as Ni, Co or Ti, on the exposed portions of the epitaxial source/drain regions 232, performing an annealing process that causes the metal to selectively react with the exposed portions of the epitaxial source/drain regions 232, followed by removing unreacted portions of the metal, leaving the silicide layer 284, respectively on the epitaxial source/drain regions 232. In some embodiments, the electrical conductivity of the silicide layer 284 is greater than the electrical conductivity of the epitaxial source/drain regions 232. In some embodiments, the source/drain contacts 258₂ have an electrical conductivity greater than the silicide layer 284.

In some embodiments, the interconnect structure 248 may be formed by damascene process, dual-damascene process, combinations thereof, or the like. For example, a trench etching process may be conducted to form a plurality of trenches. Subsequently, a metallic material like copper may be provided in the trenches as a medium for electrical transmission. Consequently, the interconnect structure 248 may be formed as a part of an integrated circuit in the semiconductor device.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that by forming gate isolation structures using oxidizer-free deposition through siloxane precursor activation and plasma polymerization, the oxidation of the gate metal layer 246 of the gate structures can be mitigated and threshold voltage (Vₜ) shift can be reduced. Oxidizer-free deposition may be performed using bottom-up flowable deposition to dissolve void formation issue from PEALD process and prevent electrical short between source/drain contacts. The gate isolation structures may include SiOCₓ with low k, such as lower than about 4 to reduce resistance-capacitance (RC) delay effect, by lowering effective capacitance (C_{eff}), thus boosting ring oscillator (RO) performance.

In some embodiments, a method of forming a semiconductor device includes the following steps. A first active region and a second active region are formed over a substrate. An isolation feature is formed over the substrate and between the first active region and the second active region along a direction. A first gate structure is formed over the first active region and a second gate structure over the second active region. A gate isolation feature is formed disposed between the first gate structure and the second gate structure along the direction, wherein the gate isolation feature includes a first portion over the isolation feature and a second portion extending into the isolation feature, and the gate isolation feature includes SiOC with a k value less than about 4. In some embodiments, forming the gate isolation feature comprises forming the gate isolation feature using flowable chemical vapor deposition. In some embodiments, forming the gate isolation feature comprises pulsing a first precursor to the substrate pulsing a second precursor to the substrate and pulsing a reactant to the substrate to cleave the first precursor and the second precursor. In some embodiments, the first precursor is a siloxane precursor. In some embodiments, the first precursor comprises an Si—O—R group. In some embodiments, the second precursor is a siloxane precursor. In some embodiments, the second precursor comprises an Si—H group. In some embodiments, the reactant comprises NHₓ gas, Ar gas, H₂ gas, or a combination thereof. In some embodiments, the first precursor, the second precursor and the reactant are oxidizer free.

In some embodiments, a method of forming a semiconductor device comprises the following steps. A first active region and a second active region are formed over a substrate. An isolation feature is formed over the substrate and between the first active region and the second active region along a direction. A first gate structure is formed over the first active region and a second gate structure over the second active region. A source/drain feature is formed over the substrate. A contact etch stop layer (CESL) is formed extending along a sidewall of the first gate structure and a sidewall of the second gate structure. An interlayer dielectric (ILD) layer is formed over the CESL, wherein the CESL between the ILD layer and the source/drain feature comprises a non-linear profile. A gate isolation feature is formed disposed between the first gate structure and the second gate structure along the direction, wherein the gate isolation feature includes a first portion over the isolation feature and a second portion extending into the isolation feature, and the gate isolation feature includes SiOC with a k value less than about 4. In some embodiments, the gate isolation feature has an upper sidewall, a curved middle sidewall, and a lower sidewall, and the curved middle sidewall is between the upper sidewall and the lower sidewall. In some embodiments, the curved middle sidewall is convex. In some embodiments, the curved middle sidewall is above the isolation feature. In some embodiments, the gate isolation feature has a top width different from a bottom width. In some embodiments, the gate isolation feature has a top width greater than a bottom width. In some embodiments, the gate isolation feature comprises a carbon concentration in a range from about 0 to about 60%. In some embodiments, forming the gate isolation feature comprises a bottom-up growth of the gate isolation feature.

In some embodiments, a semiconductor device comprises a first channel region and a second channel region extending over a substrate, an isolation feature disposed over the substrate and between the first channel region and the second channel region, a first gate stack disposed over the first channel region and the isolation feature, a second gate stack disposed over the second channel region and the isolation feature, a gate spacer disposed along a sidewall of the first gate stack, and a gate isolation feature disposed between the first gate stack and the second gate stack. The first gate stack comprises a gate dielectric layer and a gate electrode over the gate dielectric layer, wherein a bottom surface of the gate spacer is lower than a top surface of the first channel region, wherein a dielectric constant of the gate spacer is less than a dielectric constant of the gate dielectric layer. The gate isolation feature has a first curved sidewall. In some embodiments, the gate isolation feature comprises a second curved sidewall opposite to the first curved sidewall. In some embodiments, the gate isolation feature is seam free.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a first active region and a second active region over a substrate;
forming an isolation feature over the substrate and between the first active region and the second active region along a direction;
forming a first gate structure over the first active region and a second gate structure over the second active region; and
forming a gate isolation feature disposed between the first gate structure and the second gate structure along the direction, wherein the gate isolation feature includes a first portion over the isolation feature and a second portion extending into the isolation feature, and the gate isolation feature includes SiOC with a k value less than about 4.

2. The method of claim 1, wherein forming the gate isolation feature comprises:
forming the gate isolation feature using flowable chemical vapor deposition.

3. The method of claim 1, wherein forming the gate isolation feature comprises:
pulsing a first precursor to the substrate;
pulsing a second precursor to the substrate; and
pulsing a reactant to the substrate to cleave the first precursor and the second precursor.

4. The method of claim 3, wherein the first precursor is a siloxane precursor.

5. The method of claim 3, wherein the first precursor comprises an Si—O—R group.

6. The method of claim 3, wherein the second precursor is a siloxane precursor.

7. The method of claim 3, wherein the second precursor comprises an Si—H group.

8. The method of claim 3, wherein the reactant comprises NHₓ gas, Ar gas, H₂ gas, or a combination thereof.

9. The method of claim 3, wherein the first precursor, the second precursor and the reactant are oxidizer free.

10. A method of forming a semiconductor device, comprising:
forming a first active region and a second active region over a substrate;
forming an isolation feature over the substrate and between the first active region and the second active region along a direction;
forming a first gate structure over the first active region and a second gate structure over the second active region;
forming a source/drain feature over the substrate;
forming a contact etch stop layer (CESL) extending along a sidewall of the first gate structure and a sidewall of the second gate structure;
forming an interlayer dielectric (ILD) layer over the CESL, wherein the CESL between the ILD layer and the source/drain feature comprises a non-linear profile; and
forming a gate isolation feature disposed between the first gate structure and the second gate structure along the direction, wherein the gate isolation feature includes a first portion over the isolation feature and a second portion extending into the isolation feature, and the gate isolation feature includes SiOC with a k value less than about 4.

11. The method of claim 10, wherein the gate isolation feature has an upper sidewall, a curved middle sidewall, and a lower sidewall, and the curved middle sidewall is between the upper sidewall and the lower sidewall.

12. The method of claim 11, wherein the curved middle sidewall is convex.

13. The method of claim 12, wherein the curved middle sidewall is above the isolation feature.

14. The method of claim 11, wherein the gate isolation feature has a top width different from a bottom width.

15. The method of claim 11, wherein the gate isolation feature has a top width greater than a bottom width.

16. The method of claim 10, wherein the gate isolation feature comprises a carbon concentration in a range from about 0 to about 60%.

17. The method of claim 10, wherein forming the gate isolation feature comprises a bottom-up growth of the gate isolation feature.

18. A semiconductor device, comprising:
a first channel region and a second channel region extending over a substrate;
an isolation feature disposed over the substrate and between the first channel region and the second channel region;
a first gate stack disposed over the first channel region and the isolation feature;
a second gate stack disposed over the second channel region and the isolation feature;
a gate spacer disposed along a sidewall of the first gate stack, wherein the first gate stack comprises a gate dielectric layer and a gate electrode over the gate dielectric layer, wherein a bottom surface of the gate spacer is lower than a top surface of the first channel region, wherein a dielectric constant of the gate spacer is less than a dielectric constant of the gate dielectric layer; and
a gate isolation feature disposed between the first gate stack and the second gate stack, wherein the gate isolation feature has a first curved sidewall.

19. The semiconductor device of claim 18, wherein the gate isolation feature comprises a second curved sidewall opposite to the first curved sidewall.

20. The semiconductor device of claim 18, wherein the gate isolation feature is seam free.
